(19) United States
(12) Patent Application Publication
(10) Pub. No.: US 2014/0019819 A1
(43) Pub. Date: Jan. 16, 2014

(54) RECEIVER AND RECEIVING METHOD

(71) Applicant: KABUSHIKI KAISHA TOSHIBA, Tokyo (JP)

(72) Inventors: Toshiyuki NAKANISHI, Yokohama-shi (JP); Hironori UCHIKAWA, Fujisawa-shi (JP); Zhixiang CHEN, Sagamihara-shi (JP)

(21) Appl. No.: 13/936,040

(22) Filed: Jul. 5, 2013

(30) Foreign Application Priority Data
Jul. 10, 2012 (JP) 2012-154937

(51) Int. Cl. H03M 13/11

(52) U.S. Cl. CPC H03M 13/11
USPC 714/752

(57) ABSTRACT

According to an embodiment, a receiver includes a generation unit and a scheduler. The generation unit generates a convergence indicator for evaluating a convergence status of the iterative decoding process based on reliability information. The scheduler controls execution of local iteration includes the iterative decoding process terminates and controls execution of global iteration includes alternation between a symbol de-mapping process and an iterative decoding process, based on the convergence indicator.

### CROSS-REFERENCE TO RELATED APPLICATIONS

This application is based upon and claims the benefit of priority from Japanese Patent Application No. 2012-154937, filed Jul. 10, 2012, the entire contents of which are incorporated herein by reference.

### FIELD

Embodiments described herein relate generally to an iterative de-mapping and decoding technique.

### BACKGROUND

A certain kind of transmitter carries out a low-density parity check (LDPC) encoding process on a bit sequence to be transmitted and carries out an interleave process on the codeword bit sequence to generate an interleaved bit sequence. Moreover, the transmitter maps the interleaved bit sequence to constellation symbols (hereinafter referred to as symbols) on an I-Q plane, and transmits the mapped symbols.

To reproduce the bit sequence transmitted by the transmitter, a receiver needs to carry out a de-mapping process, a de-interleave process, and an LDPC decoding process on the received symbols. In general, an LDPC decoder employs an iterative decoding process and achieves a low bit error rate (BER). Moreover, in recent years, a technique referred to as iterative de-mapping and decoding (ID) has been proposed which enables better BER performance to be achieved.

ID includes local iteration comprising an iterative decoding process in the LDPC decoder and global iteration comprising alternations between a symbol de-mapping process and an iterative decoding process. Specifically, if the iterative decoding process fails to provide a correct codeword, reliability information on each bit resulting from the iterative decoding process is fed back to a symbol de-mapper. Based on the reliability information on each bit fed back by the LDPC decoder, the symbol de-mapper carries out a symbol de-mapping process (that is, calculation of reliability information on each bit) again. Based on the reliability information on each bit recalculated by the symbol de-mapper, the LDPC decoder carries out an iterative decoding process again. If the transmitter is carrying out an interleave process, the global iteration includes a de-interleave process and an interleave process.

In the conventional ID, a termination condition for the local iteration is defined by the number of trials of the local iteration. Moreover, the number of trials for the termination condition is fixed regardless of the number of trials of the global iteration. That is, in the conventional ID, even if the convergence status of the iterative decoding process is good enough to expect that the decoding will be successfully completed by further continuing the local iteration, the local iteration terminates when a specified number of trials have been performed (such a phenomenon is hereinafter referred to as early termination). On the other hand, even if the convergence status of the iterative decoding process is bad enough to expect that the reliability information on each bit will not improve even by further continuing the local iteration, the local iteration does not terminate until the specified number of trials are finished (such a phenomenon is hereinafter referred to as late termination).

The early termination involves re-execution of operations of an interleaver, the symbol de-mapper, and a de-interleaver. Moreover, the LDPC decoder needs to start the iterative decoding process all over again based on the reliability information on each bit recalculated by the symbol de-mapper. Hence, the early termination involves a significant processing delay compared to a case where the local iteration is continuously carried out after a specified number of trials of the local iteration.

The late termination means an excessive number of trials of the local iteration. Hence, the late termination involves a significant processing delay compared to a case where the local iteration is terminated before a specified number of trials of the local iteration are completed.

### BRIEF DESCRIPTION OF THE DRAWINGS

FIG. 1 is a block diagram illustrating a receiver according to a first embodiment;

FIG. 2 is a block diagram illustrating a transmitter and a channel assumed in the first embodiment;

FIG. 3 is a flowchart illustrating an operation of the receiver according to the first embodiment;

FIG. 4 is a diagram illustrating a convergence indicator; and

FIG. 5 is a flowchart illustrating an operation of a receiver according to a fourth embodiment.

### DETAILED DESCRIPTION

Embodiments will be described below with reference to the drawings.

According to an embodiment, a receiver includes a symbol de-mapper, a first extrinsic information calculation unit, an LDPC decoder, a second extrinsic information calculation unit, a generation unit and a scheduler. The symbol de-mapper carries out a symbol de-mapping process of calculating first reliability information indicative of a result of estimation of each bit mapped on the received symbols. The first reliability information is calculated based on the received symbols and second reliability information corresponding to second extrinsic information. The first extrinsic information calculation unit calculates a difference between the first reliability information and the second reliability information to obtain first extrinsic information. The LDPC decoder carries out an iterative decoding process of iteratively calculating fourth reliability information indicative of a result of estimation of each bit forming the received symbols based on third reliability information corresponding to the first extrinsic information. The second extrinsic information calculation unit calculates a difference between the third reliability information and the fourth reliability information to obtain the second extrinsic information when local iteration comprising the iterative decoding process terminates. The generation unit generates a convergence indicator for evaluating a convergence status of the iterative decoding process based on the fourth reliability information. The scheduler controls execution of the local iteration and controls execution of global iteration comprising alternation between the symbol de-mapping process and the iterative decoding process, based on the convergence indicator.

Elements which are the same as or similar to described elements are denoted by the same or similar reference numbers, and duplicate descriptions are basically omitted.

### First Embodiment

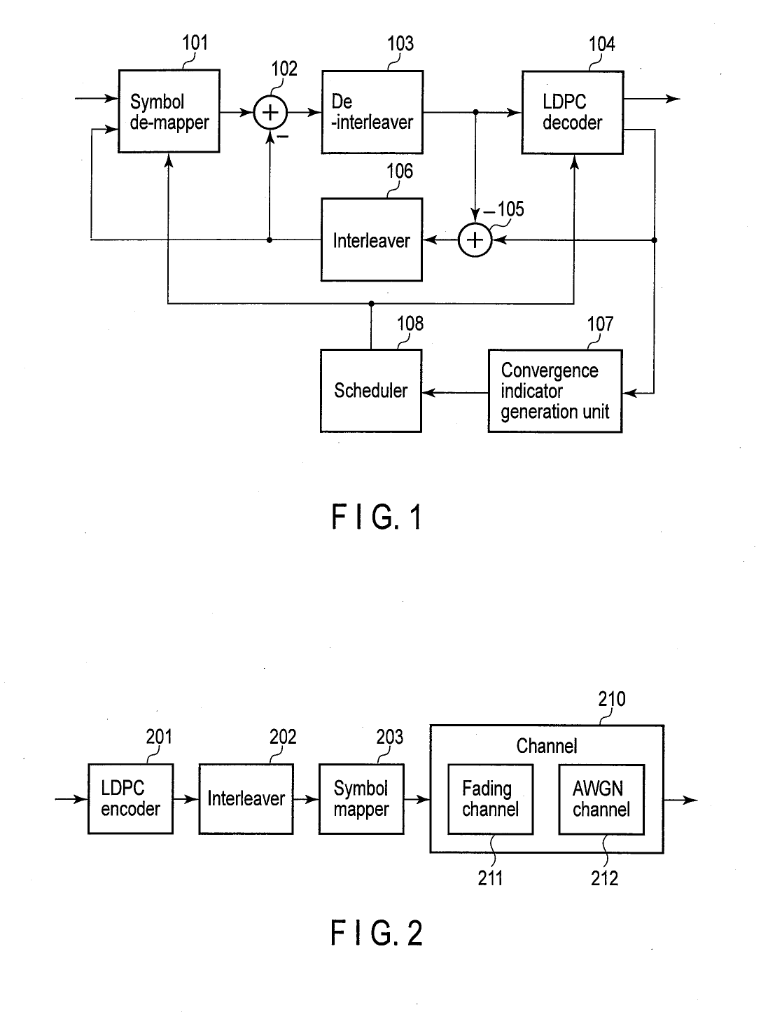

As shown in FIG. 1, a receiver according to a first embodiment comprises a symbol de-mapper 101, an extrinsic information calculation unit 102, a de-interleaver 103, an LDPC decoder 104, an extrinsic information calculation unit 105, an interleaver 106, a convergence indicator generation unit 107, and a scheduler 108.

The receiver in FIG. 1 receives symbols, for example, via a transmitter and a channel 210 shown in FIG. 2. According to the example shown in FIG. 2, the transmitter comprises an LDPC encoder 201, an interleaver 202, and a symbol mapper 203. The LDPC encoder 201 carries out an LDPC encoding process on a bit sequence to be transmitted to obtain a codeword bit sequence. The interleaver 202 carries out an interleave process on the codeword bit sequence to obtain an interleaved bit sequence. The symbol mapper 203 maps the interleaved bit sequence to symbols to obtain mapped symbols. The mapped symbols are transmitted to the symbol de-mapper 101 in FIG. 1 via the channel 210.

The channel 210 is assumed to include a fading channel 211 and an additive white Gaussian noise (AWGN) channel 212. That is, a transmission symbol sequence from the transmitter in FIG. 2 is subjected to fading and additive white Gaussian noise, and the resultant transmission symbol sequence is received by the receiver in FIG. 1.

Elements not drawn in FIG. 1 and FIG. 2 (for example, an antenna and a radio frequency (RF) signal processing unit) may be provided as necessary.

The symbol de-mapper 101 inputs received symbols from the channel 210 in FIG. 2, and further receives second reliability information on each bit fed back by the LDPC decoder 104 via the extrinsic information calculation unit 105 and the interleaver 106. Based on the received symbols and the second reliability information, the symbol de-mapper 101 carries out a symbol de-mapping process of calculating first reliability information indicative of the result of estimation (for example, an estimated value and reliability) of the value of each of the bits forming the received symbols. However, in the first global iteration, the symbol de-mapper 101 needs to calculate first reliability information before the LDPC decoder 104 calculates fourth reliability information described below, and thus, the symbol de-mapper 101 does not substantially utilize the second reliability information. A process for deriving the first reliability information will be described below. The symbol de-mapper 101 outputs the first reliability information to the extrinsic information calculation unit 102.

The first reliability information is typically the log-likelihood ratio (hereinafter referred to as L_{M, p}) of an a posteriori probability in the symbol de-mapper 101. The second reliability information is typically the log-likelihood ratio (hereinafter referred to as L_{M, a}) of a priori probability in the symbol de-mapper 101.

The extrinsic information calculation unit 102 inputs the first reliability information from the symbol de-mapper 101 and the second reliability information from the interleaves 106. In the first global iteration, all of the second reliability information is zero. The extrinsic information calculation unit 102 calculates the difference between the first reliability information and the second reliability information to obtain first extrinsic information. The extrinsic information calculation unit 102 outputs the first extrinsic information to the de-interleaver 103.

The first extrinsic information is indicative of a change in reliability information caused by a symbol de-mapping process by the symbol de-mapper 101. If the first reliability information is L_{M, p} and the second reliability information is L_{M, a}, the first extrinsic information (hereinafter referred to as L_{M, e}) can be expressed by:

L_{M,e}=L_{M,p}−L_{M,a} (1)

The de-interleaver 103 carries out a de-interleave process on the first extrinsic information to obtain third reliability information. Specifically, the de-interleaver 103 carries out the inverse processing of an interleave process carried out by the interleaver 106 described below and the interleaver 202 in FIG. 2. That is, the third reliability information is obtained by changing the order of arrangement of the first extrinsic information. The de-interleaver 103 outputs the third reliability information to the LDPC decoder 104 and the extrinsic information calculation unit 105. If the de-interleaver 103 is not provided, the first extrinsic information can be used as the third reliability information. The third reliability information is typically the log-likelihood ratio (hereinafter referred to as L_{D, a}) of the a priori probability in the LDPC decoder 104.

The LDPC decoder 104 inputs the third reliability information from the de-interleaver 103. The LDPC decoder 104 carries out an iterative decoding process of iteratively calculating the fourth reliability information based on the third reliability information. The LDPC decoder 104 outputs the latest fourth reliability information to the convergence indicator generation unit 107 at every trial of local iteration. The fourth reliability information is typically the log-likelihood ratio (hereinafter referred to as L_{D, p}) of a posteriori probability in the LDPC decoder 104.

The local iteration is controllably continued or terminated by the scheduler 108 described below. For example, the scheduler 108 terminates the local iteration and the global iteration when the total number of bits failing to meet a parity constraint condition is zero during the course of the local iteration (successful decoding case). Furthermore, the scheduler 108 may terminate the local iteration while resuming the global iteration, as described below.

The LDPC decoder 104 outputs the latest fourth reliability information to the extrinsic information calculation unit 105 if the local iteration is terminated, while the global iteration is resumed. Furthermore, if both the local iteration and the global iteration are to be terminated, the LDPC decoder 104 outputs a hard decision result for the received symbols based on the latest fourth reliability information to an external element not shown in the drawings in accordance with control performed by the scheduler 108. For example, if the fourth reliability information is the log-likelihood ratio of the a posteriori probability, a hard decision of the value of each of the bits forming the received symbols can be obtained depending on whether the sign is positive or negative.

The extrinsic information calculation unit 105 inputs the fourth reliability information from the LDPC decoder 104 and the third reliability information from the de-interleaver 103 if the local iteration is terminated, while the global iteration is resumed. The extrinsic information calculation unit 105 calculates the difference between the third reliability information and the fourth reliability information to obtain second extrinsic information. The extrinsic information calculation unit 105 outputs the second extrinsic information to the interleaver 106.

The second extrinsic information is indicative of a change in reliability information caused by an iterative decoding process by the LDPC decoder 104. If the third reliability information is L_{D, a} and the fourth reliability information is L_{D, p}, the second extrinsic information (hereinafter referred to as L_{D, e}) can be expressed by:

L_{D,e}=L_{D,p}−L_{D,a} (2)

The interleaver 106 carries out an interleave process on the second extrinsic information to obtain the above-described second reliability information. Specifically, the interleaver 106 carries out the same process as the interleave process carried out by the interleaver 202 in FIG. 2 (in other words, the inverse processing of the de-interleave process carried out by the de-interleaver 103). That is, the second reliability information is obtained by changing the order of arrangement of the second extrinsic information. The interleaver 106 outputs the second reliability information to the symbol de-mapper 101 and the extrinsic information calculation unit 102. If the interleaver 106 is not provided, the second extrinsic information can be used as the second reliability information.

The convergence indicator generation unit 107 inputs the fourth reliability information from the LDPC decoder 104. The convergence indicator generation unit 107 generates a convergence indicator for evaluating the convergence status of the iterative decoding process based on the fourth reliability information. The convergence indicator will be described below in detail. The convergence indicator generation unit 107 outputs the convergence indicator to the scheduler 108.

The scheduler 108 inputs the convergence indicator from the convergence indicator generation unit 107. The scheduler 108 controls the execution of the local iteration and the global iteration based on the convergence indicator. Specifically, the scheduler 108 controllably continues or terminates the local iteration based on the convergence indicator. Moreover, the scheduler 108 controllably resumes or terminates the global iteration when it terminates the local iteration. That is, the scheduler 108 determines to terminate both the local iteration and the global iteration, to continue the local iteration, or to terminate the local iteration while resuming the global iteration. For example, if the total number of bits failing to meet the parity constraint condition is zero, the scheduler 108 terminates both the local iteration and the global iteration.

Now, a course in which the symbol de-mapper 101 derives the first reliability information will be described. The description below assumes that one symbol is formed by m bits b₀, b₁, . . . , bₘ₋₁. Furthermore, the reliability information is expressed by the log-likelihood ratio of the a priori probability or the a posteriori probability.

Under the condition that the received symbol is z, the reliability information on the i+1^{th} bit bᵢ is defined by:

$$L ( {b}_{i} \vert z ) = ln ( \frac{Pr ( {b}_{i} = 1 \vert z )}{Pr ( {b}_{i} = 0 \vert z )} ) \qquad ( 3 )$$

The reliability information in Expression (3) has a positive value if the bit bᵢ is likely to be 1 or a negative value if the bit bᵢ is likely to be 0. Moreover, the reliability information in Expression (3) has an absolute value increasing consistently with reliability in bit estimation. The reliability information in Expression (3) has a positive value with an absolute value increasing consistently with the possibility that the bit bᵢ is 1 and has a negative value with an absolute value increasing consistently with the possibility that the bit bᵢ is 0.

Applying Bayes' theorem shown below in Expression (4) to Expression (3) allows the reliability information in Expression (3) to be rewritten as shown below in Expression (5).

$$\begin{matrix}Pr ( A \vert B ) \cdot Pr ( B ) = Pr ( B \vert A ) \cdot Pr ( A ) & ( 4 ) \\ \begin{matrix}L ( {b}_{i} \vert z ) = ln ( \frac{Pr ( {b}_{i} = 1 \vert z )}{Pr ( {b}_{i} = 0 \vert z )} ) \\ = ln ( \frac{Pr ( z \vert {b}_{i} = 1 )}{Pr ( z \vert {b}_{i} = 0 )} )\end{matrix} & ( 5 )\end{matrix}$$

Furthermore, the use of an imaginary unit j allows the received symbol to be expressed by z=z_{I}+j·z_{Q} and allows the transmission symbol to be expressed by y=y_{I}+j·y_{Q}. Moreover, the gain of the fading channel 211 in FIG. 2 can be expressed by ρ=ρ_{I}+j·p_{Q}. The noise power in the AWGN channel in FIG. 2 can be expressed by σ². Using these relations, the conditional probability distribution of the received symbol z under the condition that the bit bᵢ=1 can be expressed by:

$$Pr ( z \vert {b}_{i} = 1 ) = \frac{1}{{2}^{m} {πσ}^{2}} {\sum }_{x ∈ {C}_{i}^{1}} ( exp ( - \frac{{( {z}_{I} - {ρ}_{I} {y}_{I} )}^{2} + {( {z}_{Q} - {ρ}_{Q} {y}_{Q} )}^{2}}{2 {σ}^{2}} ) {Pr}_{apriori} ( x \vert {b}_{i} = 1 ) ) \qquad ( 6 )$$

In Expression (6), the total number of bits forming the symbol is denoted by m, and a set of symbols for bᵢ=j which are included in the symbols defined on a constellation is denoted by Cᵢ^{j}. The conditional probability (a priori probability) that the transmission symbol matches x under the condition that bᵢ=1 is denoted by Pr_{a priori} (x|bᵢ=1). When the a posteriori probability of each bit in the LDPC decoder 104 is expressed by Expression (7) and Expression (8) shown below, Pr_{a priori} (x|bᵢ=1) can be expressed by:

$$\begin{matrix}{Pr}_{LDPC} ( b = 0 ) = \frac{1}{1 + exp ( {L}_{D , e} ( b ) )} & ( 7 ) \\ {Pr}_{LDPC} ( b = 1 ) = 1 - {Pr}_{LDPC} ( b = 0 ) & ( 8 ) \\ {Pr}_{apriori} ( x \vert {b}_{i} = 1 ) = {\prod }_{k \neq i} {Pr}_{LDPC} ( {b}_{k} = {x}_{k} ) & ( 9 )\end{matrix}$$

Expression (10) shown below can be derived from Expression (5) to Expression (9).

$$\begin{matrix}L ( {b}_{i} \vert z ) = ln \frac{{\sum }_{x ∈ {C}_{i}^{1}} ( exp ( - \frac{{( {z}_{I} - {ρ}_{I} {y}_{I} )}^{2} + {( {z}_{Q} - {ρ}_{Q} {y}_{Q} )}^{2}}{2 {σ}^{2}} ) {\prod }_{k \neq i} {Pr}_{LDPC} ( {b}_{k} = {x}_{k} ) )}{{\sum }_{x ∈ {C}_{i}^{0}} ( exp ( - \frac{{( {z}_{I} - {ρ}_{I} {y}_{I} )}^{2} + {( {z}_{Q} - {ρ}_{Q} {y}_{Q} )}^{2}}{2 {σ}^{2}} ) {\prod }_{k \neq i} {Pr}_{LDPC} ( {b}_{k} = {x}_{k} ) )} \\ = ln \frac{{\sum }_{x ∈ {C}_{i}^{1}} ( exp ( - \frac{{( {z}_{I} - {ρ}_{I} {y}_{I} )}^{2} + {( {z}_{Q} - {ρ}_{Q} {y}_{Q} )}^{2}}{2 {σ}^{2}} + {\sum }_{k \neq i and {x}_{k} = 1} {L}_{D , e} ( {b}_{k} ) ) )}{{\sum }_{x ∈ {C}_{i}^{0}} ( exp ( - \frac{{( {z}_{I} - {ρ}_{I} {y}_{I} )}^{2} + {( {z}_{Q} - {ρ}_{Q} {y}_{Q} )}^{2}}{2 {σ}^{2}} + {\sum }_{k \neq i and {x}_{k} = 1} {L}_{D , e} ( {b}_{k} ) ) )}\end{matrix} \qquad ( 10 )$$

In Expression (10), L_{M, a} is obtained by rearranging the order of L_{D, e}. Hence, each of the elements contained in L_{M, a} matches one of the elements contained in L_{D, e}, and each of the elements contained in L_{D, e} matches one of the elements contained in L_{M, a}. That is, Expression (10) holds true even if L_{D, e} is replaced with L_{M, a}. Applying Max-log approximation to Expression (10) and replacing L_{D, e} with L_{M, a} results in:

$$L ( {b}_{i} \vert z ) \approx {min}_{x ∈ {C}_{i}^{1}} ( \frac{{( {z}_{I} - {ρ}_{I} {y}_{I} )}^{2} + {( {z}_{Q} - {ρ}_{Q} {y}_{Q} )}^{2}}{2 {σ}^{2}} - {\sum }_{k \neq i and {x}_{k} = 1} {L}_{M , a} ( {b}_{k} ) ) - {min}_{x ∈ {C}_{i}^{0}} ( \frac{{( {z}_{I} - {ρ}_{I} {y}_{I} )}^{2} + {( {z}_{Q} - {ρ}_{Q} {y}_{Q} )}^{2}}{2 {σ}^{2}} - {\sum }_{k \neq i and {x}_{k} = 1} {L}_{M , a} ( {b}_{k} ) ) \qquad ( 11 )$$

The symbol de-mapper 101 can calculate (bi|z) in Expression (11) to be the first reliability information.

In the present embodiment, the convergence indicator generation unit 107 may generate a convergence indicator indicative of the total number of bits failing to meet the parity constraint condition.

In the description below, the total number of bits failing to meet the parity constraint condition after the l^{th} trial of the local iteration is expressed by n_{usp, 1}. The value n_{usp, l} can be calculated using a hard decision result based on the fourth reliability information on each of the bits forming the received symbol and a parity check matrix used by the LDPC decoder 104. Preferably, during the course of the local iteration, the value n_{usp, l} gradually decreases and finally becomes zero. Thus, a smaller value n_{usp, l} corresponds to a better convergence status of the iterative decoding process.

In the present embodiment, the scheduler 108 may use the value n_{usp, l} being less than a threshold value (hereinafter referred to as nₜₕ [≦1]) as at least a part of the condition for continuing the local iteration. For example, even if the number of trials of the local iteration (hereinafter referred to as l) is greater than or equal to a first specified number of times (hereinafter referred to as Nₗ [≧1]), the scheduler 108 continues the local iteration if the value n_{usp, l} is less than nₜₕ.

Moreover, the scheduler 108 may use the value n_{usp, l} being greater than or equal to nₜₕ as at least a part of a condition for terminating the local iteration and resuming the global iteration. For example, the scheduler 108 terminates the local iteration while resuming the global iteration if the value 1 is greater than or equal to Nₗ and if the value n_{usp, l} is greater than or equal to nₜₕ.

That is, in the present embodiment, the scheduler 108 determines, for example, whether or not the following condition is met.

(1≧Nₗ) [symbol] (n_{usp,l}≧nₜₕ)

If this condition is met, the scheduler 108 terminates the local iteration while resuming the global iteration. If the condition is not met, the scheduler 108 continues the local iteration.

The value Nₗ functions as a lower limit on the number of trials of the local iteration. In general, the increased value Nₗ allows possible early termination described above to be more easily prevented. The reduced value Nₗ allows possible late termination described above to be more easily prevented. The value Nₗ may be fixed regardless of the number of trials of the global iteration or may vary at every trial of the global iteration. Furthermore, the value nₜₕ may be fixed regardless of the number of trials of the global iteration or the local iteration or may vary at every trial of the global iteration or the local iteration.

Even when the number of trials of the local iteration has reached the first specified number of times, the scheduler 108 continues the local iteration if the convergence status is good. On the other hand, if the convergence is bad, the scheduler 108 terminates the local iteration while resuming the global iteration when the number of trials of the local iteration reaches the first specified number of times. That is, the scheduler 108 adaptively controllably continues or terminates the local iteration depending on the convergence status of the iterative decoding process. Thus, possible early termination and late termination described above can be prevented.

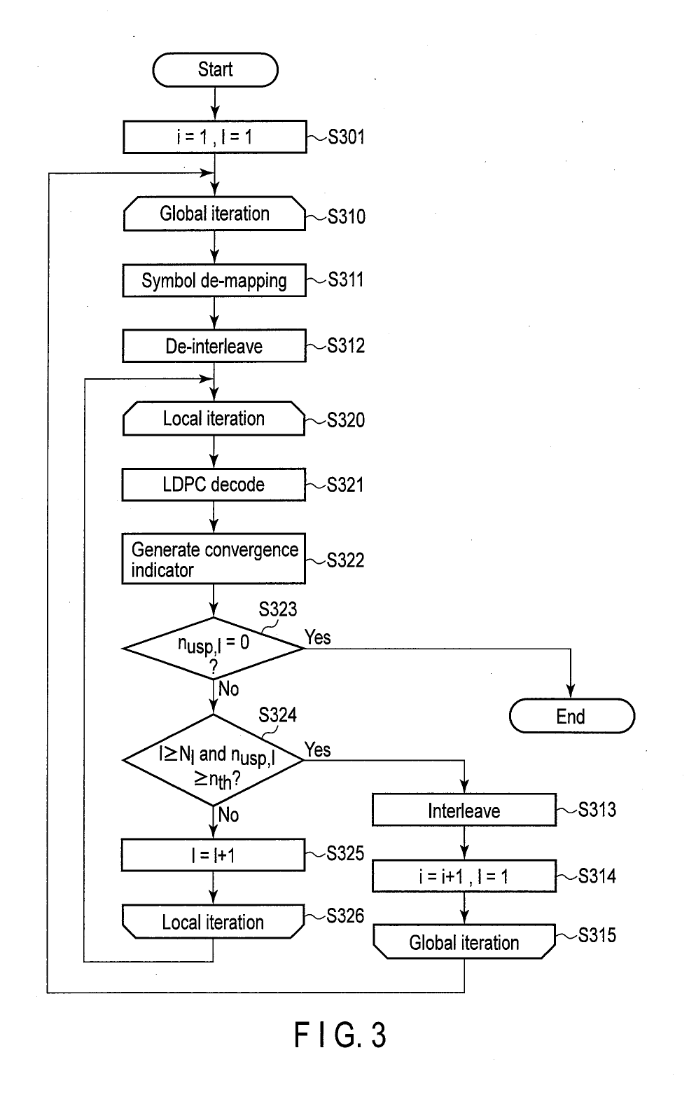

The receiver according to the present embodiment operates as illustrated in FIG. 3. The operation in FIG. 3 starts with step S301.

In step S301, the scheduler 108 initializes a variable i and a variable l. According to the example in FIG. 3, the initialization means substitution of 1 into the variables i and l. The variable i is indicative of the number of trials of the global iteration. The variable l is indicative of the number of trials of the local iteration and is reset at every trial of the global iteration. Step S301 is followed by the start of the i^{th} global iteration (step S310).

When the global iteration starts, the scheduler 108 operates the symbol de-mapper 101 (step S311). In step S311, the symbol de-mapper 101 carries out a symbol de-mapping process of calculating the first reliability information based on the received symbol and the second reliability information.

The de-interleaver 103 carries out a de-interleave process on the first extrinsic information based on the first reliability information calculated in step S311 to obtain the third reliability information (step S312). Step S312 is followed by the start of the l^{th} local iteration in the i^{th} global iteration (step S320).

When the local iteration starts, the scheduler 108 operates the LDPC decoder 104 (step S321). In step S321, the LDPC decoder 104 carries out a single iterative decoding process of calculating the fourth reliability information based on the third reliability information. The convergence indicator generation unit 107 generates a convergence indicator based on the fourth reliability information calculated in step S321 (step S322). According to the example in FIG. 3, the convergence indicator is n_{usp, l} described above.

Based on the value n_{usp, l} generated in step S322, the scheduler 108 determines whether the iterative decoding process has succeeded or failed (step S323). Specifically, if the value n_{usp, l} is zero, the scheduler 108 determines that the iterative decoding process has succeeded and terminates both the local iteration and the global iteration. On the other hand, if the value n_{usp, l} is not zero, the scheduler 108 determines that the iterative decoding process has not succeeded. The processing proceeds to step S324.

In step S324, if the value l is greater than or equal to Nₗ and the value n_{usp, l} is greater than or equal to nₜₕ, the scheduler 108 determines to terminate the local iteration and to resume the global iteration. The processing proceeds to step S313. On the other hand, in step S324, if the value l is less than Nₗ or the value n_{usp, l} is less than nₜₕ, the scheduler 108 determines to continue the local iteration. The processing proceeds to step S325. In step S325, the scheduler 108 increments the value l by one. Step S325 is followed by the termination of the l−1^{th} local iteration in the i^{th} global iteration (step S326). The processing returns to step S320.

In step S326, if the value 1 has reached the second specified number of times (>Nₗ), the scheduler 108 may terminate the local iteration. The second specified number of times functions as an upper limit on the number of trials of the local iteration. Hence, setting the second specified number of times enables prevention of a situation in which the local iteration continues redundantly for an extended time when the convergence status of the iterative decoding process is not expected to be further improved though the value n_{usp, l} is less than nₜₕ.

In step S313, the interleaver 106 carries out an interleave process on the second extrinsic information based on the fourth reliability information to obtain the second reliability information. The scheduler 108 increments the value i by one and resets the value l (step S314). Resetting means substation of 1 into the value l according to the example in FIG. 3. Step S314 is followed by the start of the i^{th} global iteration terminates (step S315). The processing returns to step S310. In step S315, if the value i has reached a third specified number of times, the scheduler 108 may terminate the global iteration. The third specified number of times functions as an upper limit on the number of trials of the global iteration. Hence, setting the third specified number of times enables redundant continuation of the ID for an extended time to be prevented.

As described above, the receiver according to the first embodiment performs evaluation by determining the convergence status to be better when the total number of bits failing to meet the parity constraint condition is smaller. The receiver uses a good convergence status as at least a part of the condition for continuing the local iteration and uses a bad convergence status as at least a part of the condition for terminating the local iteration while resuming the global iteration. Thus, the receiver adaptively controls the execution of the local iteration and the global iteration depending on the convergence status of the iterative decoding process. Hence, the receiver can prevent possible early termination and late termination described above.

### Second Embodiment

A receiver according to a second embodiment differs from the receiver according to the first embodiment in a part of the operations of the convergence indicator generation unit 107 and the scheduler 108.

Specifically, the scheduler 108 according to the present embodiment controls the execution of the local iteration and the global iteration by focusing on the change in n_{usp, l} (hereinafter referred to as Δn_{usp, l}) instead of the value n_{usp, l} itself. The convergence indicator generation unit 107 may generate Δn_{usp, l} as a convergence indicator or generate n_{usp, l} as a convergence indicator as is the case with the first embodiment. If the convergence indicator generation unit 107 does not generate Δn_{usp, l}, the scheduler 108 may calculate Δn_{usp, l} based on n_{usp, l}.

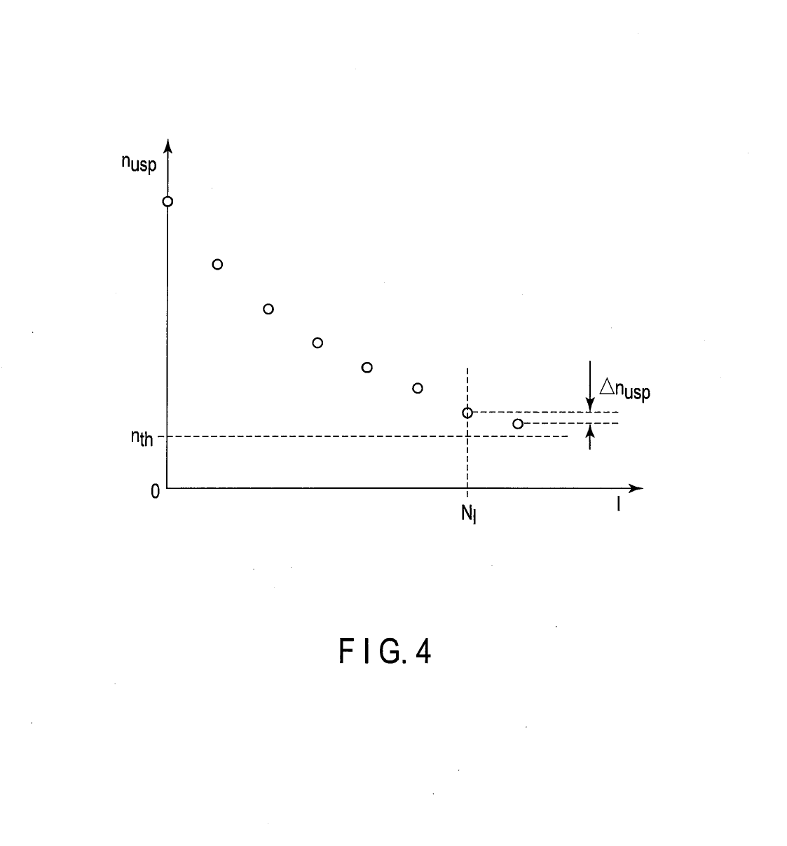

The value Δn_{usp, l} may be defined by, for example, n_{usp, l}−n_{usp, l-1}. According to this definition, the value Δn_{usp, l} represents the change based on the total number of bits failing to meet the parity constraint condition which number results from the l−1^{th} trial of the local iteration. Preferably, during the course of the local iteration, the value n_{usp, l} gradually decreases as illustrated in FIG. 4, and thus, the value Δn_{usp, l} is negative if the iterative decoding process appropriately converges. The value Δn_{usp, l} corresponds to the convergence speed of the iterative decoding process during the l^{th} trial of the local iteration.

According to the present embodiment, the scheduler 108 may use the value Δn_{usp, l} being less than a threshold value (hereinafter referred to as Δnₜₕ [≦0] as at least a part of the condition for continuing the local iteration. For example, even if the value 1 is greater than or equal to Nₗ, the scheduler 108 continues the local iteration when the value Δn_{usp, l} is less than Δnₜₕ.

Moreover, the scheduler 108 may use the value Δn_{usp, l} being greater than or equal to Δnₜₕ as at least a part of the condition for terminating the local iteration while resuming the global iteration. For example, the scheduler 108 terminates the local iteration while resuming the global iteration if the value l is greater than or equal to Nₗ and if the value Δn_{usp, l} is greater than or equal to Δnₜₕ.

That is, according to the present embodiment, the scheduler 108 determines whether or not, for example, the following condition is met.

(1≧Nₗ) [symbol] (Δn_{usp,l}≧Δnₜₕ)

The scheduler 108 terminates the local iteration while resuming the global iteration if the condition is met, or continues the local iteration if the condition is not met.

The value Δnₜₕ may be fixed regardless of the number of trials of the global iteration or the local iteration or may vary at every trial of the global iteration or the local iteration.

Even if the number of trials of the local iteration has reached the first specified number of times, the scheduler 108 continues the local iteration when the convergence status is good. On the other hand, if the convergence status is bad, the scheduler 108 terminates the local iteration while resuming the global iteration when the number of trials of the local iteration reaches the first specified number of times. That is, the scheduler 108 adaptively controls the execution of the local iteration and the global iteration depending on the convergence status of the iterative decoding process. Hence, the scheduler 108 can prevent possible early termination and late termination described above.

As described above, the receiver according to the second embodiment performs evaluation by determining the convergence status to be better (the convergence speed to be greater) when the change in the total number of bits failing to meet the parity constraint condition is larger in a negative direction. The receiver uses a good convergence status as at least a part of the condition for continuing the local iteration and uses a bad convergence status as at least a part of the condition for terminating the local iteration while resuming the global iteration. Thus, the receiver adaptively controls the execution of the local iteration and the global iteration depending on the convergence status of the iterative decoding process. Hence, the receiver can prevent possible early termination and late termination described above.

### Third Embodiment

A receiver according to a third embodiment differs from the receivers according to the first and second embodiments in a part of the operations of the convergence indicator generation unit 107 and the scheduler 108.

Specifically, the scheduler 108 according to the present embodiment controls the execution of the local iteration and the global iteration by focusing on both n_{usp, l} and Δn_{usp, l}. The convergence indicator generation unit 107 may generate n_{usp, l} and Δn_{usp, l} as convergence indicators or generate n_{usp, l} as a convergence indicator as is the case with the first embodiment. If the convergence indicator generation unit 107 does not generate Δn_{usp, l}, the scheduler 108 may calculate Δn_{usp, l} based on n_{usp, l}.

According to the present embodiment, the scheduler 108 may use the value n_{usp, l} being less than nₜₕ and the value Δn_{usp, l} being less than Δnₜₕ as at least a part of the condition for continuing the local iteration. For example, even if the value l is greater than or equal to Nₗ, the scheduler 108 continues the local iteration when the value n_{usp, l} is less than nₜₕ. Similarly, even if the value l is greater than or equal to Nₗ, the scheduler 108 continues the local iteration when the value Δn_{usp, l} is less than Δnₜₕ.

Moreover, the scheduler 108 may use the value n_{usp, l} being greater than or equal to nₜₕ and the value Δn_{usp, l} being greater than or equal to Δnₜₕ as at least a part of the condition for terminating the local iteration while resuming the global iteration. For example, the scheduler 108 terminates the local iteration while resuming the global iteration if the value l is greater than or equal to Nₗ and if the value n_{usp, l} and the value Δn_{usp, l} are greater than or equal to nₜₕ and Δnₜₕ, respectively.

That is, according to the present embodiment, the scheduler 108 determines whether or not, for example, the following condition is met.

(l≧Nₗ) [symbol] (n_{usp,l}≧nₜₕ) [symbol] (Δn_{usp,l}≧Δnₜₕ)

The scheduler 108 terminates the local iteration while resuming the global iteration if the condition is met, or continues the local iteration if the condition is not met.

Even if the number of trials of the local iteration has reached the first specified number of times, the scheduler 108 continues the local iteration when the convergence status is good. On the other hand, if the convergence status is bad, the scheduler 108 terminates the local iteration while resuming the global iteration when the number of trials of the local iteration reaches the first specified number of times. That is, the scheduler 108 adaptively controls the execution of the local iteration and the global iteration depending on the convergence status of the iterative decoding process. Hence, the scheduler 108 can prevent possible early termination and late termination described above.

As described above, the receiver according to the third embodiment performs evaluation by focusing on the total number of bits failing to meet the parity constraint condition and the change in the total number (the decrease in the total number). The receiver uses a good convergence status as at least a part of the condition for continuing the local iteration and uses a bad convergence status as at least a part of the condition for terminating the local iteration while resuming the global iteration. Thus, the receiver adaptively controls the execution of the local iteration and the global iteration depending on the convergence status of the iterative decoding process. Hence, the receiver can prevent possible early termination and late termination described above.

### Fourth Embodiment

A receiver according to a fourth embodiment differs from the receivers according to the first to third embodiments in a part of the operations of the convergence indicator generation unit 107 and the scheduler 108.

Specifically, the scheduler 108 according to the present embodiment controls the execution of the local iteration and the global iteration by focusing on the statistical value of the fourth reliability information (hereinafter referred to as Lₗ) instead of n_{usp, l} and Δn_{usp, l}. That is, the convergence indicator generation unit 107 generates Lₗ as a convergence indicator.

If the fourth reliability information is L_{D, p} as described above, Lₗ is, for example, the average value, median, mode, maximum value, or minimum value of the absolute value of L_{D, p} corresponding to each of the bits forming the received symbol. For example, the convergence indicator generation unit 107 may generate the average value of the absolute value of L_{D, p} as Lₗ as shown in:

$${L}_{1} = \frac{1}{w} {\sum }_{w = 0}^{W - 1} \vert {L}_{D , p , 1} ( {b}_{w} ) \vert \qquad ( 12 )$$

In Expression (12) the w+1^{th} bit b_{W} in the value L_{D, p} calculated by the l^{th} local iteration is denoted by L_{D, p, l}(b_{W}). The bit length of a symbol (that is, an LDPC codeword) is denoted by W.

As described above, the log-likelihood ratio defined by Expression (3) described above has a positive value with an absolute value increasing consistently with the possibility that the corresponding bit is 1 and has a negative value with an absolute value increasing consistently with the possibility that the bit bᵢ is 0. Hence, if the convergence status of the iterative decoding process is good, L_{D, p} has a positive value with a large absolute value or a negative value with a large absolute value.

According to the present embodiment, the scheduler 108 may use the value Lₗ being greater than or equal to a threshold value (hereinafter referred to as Lₜₕ [>0]) as at least a part of the condition for continuing the local iteration. For example, even if the value l is greater than or equal to Nₗ, the scheduler 108 continues the local iteration when the value Lₗ is greater than or equal to Lₜₕ.

Moreover, the scheduler 108 may use the value Lₗ being less than Lₜₕ as at least a part of the condition for terminating the local iteration while resuming the global iteration. For example, the scheduler 108 terminates the local iteration while resuming the global iteration if the value l is greater than or equal to Nₗ and if the value Lₗ is less than Lₜₕ.

That is, according to the present embodiment, the scheduler 108 determines whether or not, for example, the following condition is met.

(l≧Nₗ) [symbol] (Lₗ<Lₜₕ)

The scheduler 108 terminates the local iteration while resuming the global iteration if the condition is met, or continues the local iteration if the condition is not met.

The value Lₜₕ may be fixed regardless of the number of trials of the global iteration or the local iteration or may vary at every trial of the global iteration or the local iteration.

Even if the number of trials of the local iteration has reached the first specified number of times, the scheduler 108 continues the local iteration when the convergence status is good. On the other hand, if the convergence status is bad, the scheduler 108 terminates the local iteration when the number of trials of the local iteration reaches the first specified number of times. That is, the scheduler 108 adaptively controls the execution of the local iteration and the global iteration depending on the convergence status of the iterative decoding process. Hence, the scheduler 108 can prevent possible early termination and late termination described above.

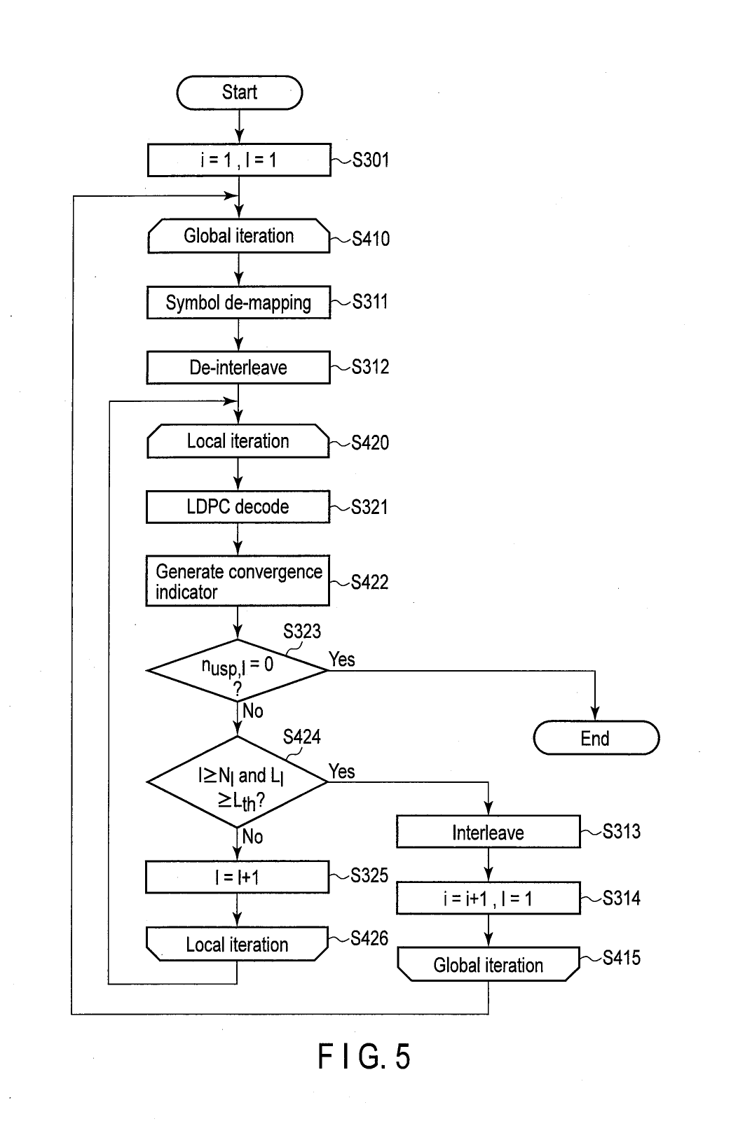

The receiver according to the present embodiment operates as illustrated in FIG. 5. The operation in FIG. 5 starts with step S301. Step S301 is followed by the start of the i^{th} global iteration (step S410). Moreover, step S312 is followed by the start of the l^{th} local iteration in the i^{th} global iteration (step S420).

The convergence indicator generation unit 107 generates a convergence indicator based on the fourth reliability information calculated in step S321 (step S422). According to the example in FIG. 5, the convergence indicator is Lₗ described above. However, the convergence indicator generation unit 107 may generate n_{usp, l} for step S323.

The scheduler 108 determines whether the iterative decoding process has succeeded or failed based on n_{usp, l} (step S323). Specifically, if the value n_{usp, l} is zero, the scheduler 108 determines that the iterative decoding process has succeeded and terminates both the local iteration and the global iteration. On the other hand, if the value n_{usp, l} is not zero, the scheduler 108 determines that the iterative decoding process has not succeeded. The processing proceeds to step S424.

In step S424, if the value l is greater than or equal to Nₗ and the value Lₗ is less than Lₜₕ, the scheduler 108 determines to terminate the local iteration and to resume the global iteration. The processing proceeds to step S313. On the other hand, in step S424, if the value l is less than Nₗ or the value Lₗ is greater than or equal to Lₜₕ, the scheduler 108 determines to continue the local iteration. The processing proceeds to step S325. Step S325 is followed by the termination of the l−1^{th} local iteration in the i^{th} global iteration (step S426). The processing returns to step S420.

In step S426, if the value l has reached the second specified number of times (>Nₗ), the scheduler 108 may terminate the local iteration. The second specified number of times functions as an upper limit on the number of trials of the local iteration. Hence, setting the second specified number of times enables prevention of a situation in which the local iteration continues redundantly for an extended time when the convergence status of the iterative decoding process is not expected to be further improved though the value Lₗ is greater than or equal to Lₜₕ.

Furthermore, step S314 is followed by the termination of the i^{th} global iteration (step S415), and the processing returns to step S410. In step S415, if the value i has reached the third specified number of times, the scheduler 108 may terminate the global iteration. The third specified number of times functions as an upper limit on the number of trials of the global iteration. Hence, setting the third specified number of times enables redundant continuation of the ID for an extended time to be prevented.

As described above, the receiver according to the fourth embodiment performs evaluation by determining the convergence status of the iterative decoding process to be better when the statistical value of the fourth reliability information (for example, the log-likelihood ratio of the a posteriori probability in the LDPC decoder) is larger. The receiver uses a good convergence status as at least a part of the condition for continuing the local iteration and uses a bad convergence status as at least a part of the condition for terminating the local iteration while resuming the global iteration. Thus, the receiver adaptively controls the execution of the local iteration and the global iteration depending on the convergence status of the iterative decoding process. Hence, the receiver can prevent possible early termination and late termination described above.

### Fifth Embodiment

A receiver according to a fifth embodiment differs from the receivers according to the first to fourth embodiments in a part of the operations of the convergence indicator generation unit 107 and the scheduler 108.

Specifically, the scheduler 108 according to the present embodiment controls the execution of the local iteration and the global iteration by focusing on the change in L_{usp, l} (hereinafter referred to as ΔL_{usp, l}) instead of the value Lₗ itself. The convergence indicator generation unit 107 may generate ΔLₗ as a convergence indicator or generate Lₗ as a convergence indicator as is the case with the fourth embodiment. If the convergence indicator generation unit 107 does not generate ΔLₗ, the scheduler 108 may calculate ΔLₗ based on Lₗ.

The value ΔLₗ may be defined by, for example, Lₗ−Lₗ₋₁. According to this definition, the value ΔLl represents the change based on the statistical value of the fourth reliability information resulting from the l−1^{th} trial of the local iteration. Preferably, during the course of the local iteration, the value Lₗ gradually increases, and thus, the value ΔLₗ is positive if the iterative decoding process appropriately converges. The value ΔLₗ corresponds to the convergence speed of the iterative decoding process during the l^{th} trial of the local iteration.

According to the present embodiment, the scheduler 108 may use the value ΔLₗ being greater than or equal to a threshold value (hereinafter referred to as ΔLₜₕ (≧0) as at least a part of the condition for continuing the local iteration. For example, even if the value l is greater than or equal to Nₗ, the scheduler 108 continues the local iteration when the value ΔLₗ is greater than or equal to ΔLₜₕ.

Moreover, the scheduler 108 may use the value ΔLₗ being less than ΔLₜₕ as at least a part of the condition for terminating the local iteration while resuming the global iteration. For example, the scheduler 108 terminates the local iteration while resuming the global iteration if the value l is greater than or equal to Nₗ and if the value ΔLₗ is less than ΔLₜₕ.

That is, according to the present embodiment, the scheduler 108 determines whether or not, for example, the following condition is met.

(l≧Nₗ) [symbol] (ΔLₗ<ΔLₜₕ)

The scheduler 108 terminates the local iteration while resuming the global iteration if the condition is met, or continues the local iteration if the condition is not met.

The value ΔLₜₕ may be fixed regardless of the number of trials of the global iteration or the local iteration or may vary at every trial of the global iteration or the local iteration.

Even if the number of trials of the local iteration has reached the first specified number of times, the scheduler 108 continues the local iteration when the convergence status is good. On the other hand, if the convergence status is bad, the scheduler 108 terminates the local iteration while resuming the global iteration when the number of trials of the local iteration reaches the first specified number of times. That is, the scheduler 108 adaptively controls the execution of the local iteration and the global iteration depending on the convergence status of the iterative decoding process. Hence, the scheduler 108 can prevent possible early termination and late termination described above.

As described above, the receiver according to the fifth embodiment performs evaluation by determining the convergence status to be better (the convergence speed to be greater) when the change in the statistical value of the fourth reliability information (for example, the log-likelihood ratio of the a posteriori probability in the LDPC decoder) is larger in a positive direction. The receiver uses a good convergence status as at least a part of the condition for continuing the local iteration and uses a bad convergence status as at least a part of the condition for terminating the local iteration while resuming the global iteration. Thus, the receiver adaptively controls the execution of the local iteration and the global iteration depending on the convergence status of the iterative decoding process. Hence, the receiver can prevent possible early termination and late termination described above.

### Sixth Embodiment

A receiver according to a third embodiment differs from the receivers according to the first to fifth embodiments in a part of the operations of the convergence indicator generation unit 107 and the scheduler 108.

Specifically, the scheduler 108 according to the present embodiment controls the execution of the local iteration and the global iteration by focusing on both Lₗ and ΔLₗ. The convergence indicator generation unit 107 may generate Lₗ and ΔLₗ as convergence indicators or generate Lₗ as a convergence indicator as is the case with the fourth embodiment. If the convergence indicator generation unit 107 does not generate ΔLₗ, the scheduler 108 may calculate ΔLₗ based on Lₗ.

According to the present embodiment, the scheduler 108 may use the value Lₗ being greater than or equal to Lₜₕ and the value ΔLₗ being greater than or equal to ΔLₜₕ as at least a part of the condition for continuing the local iteration. For example, even if the value l is greater than or equal to Nₗ, the scheduler 108 continues the local iteration when the value Lₗ is greater than or equal to Lₜₕ. Similarly, even if the value l is greater than or equal to Nₗ, the scheduler 108 continues the local iteration when the value ΔLₗ is greater than or equal to ΔLₜₕ.

Moreover, the scheduler 108 may use the value Lₗ being less than Lₜₕ and the value ΔLₗ being less than ΔLₜₕ as at least a part of the condition for terminating the local iteration while resuming the global iteration. For example, the scheduler 108 terminates the local iteration while resuming the global iteration if the value l is greater than or equal to Nₗ and if the value Lₗ and the value ΔLₗ are less than Lₜₕ and ΔLₜₕ, respectively.

That is, according to the present embodiment, the scheduler 108 determines whether or not, for example, the following condition is met.

(l≧Nₗ) [symbol] (Lₗ<Lₜₕ) [symbol] (ΔLₗ<ΔLₜₕ)

The scheduler 108 terminates the local iteration while resuming the global iteration if the condition is met, or continues the local iteration if the condition is not met.

Even if the number of trials of the local iteration has reached the first specified number of times, the scheduler 108 continues the local iteration when the convergence status is good. On the other hand, if the convergence status is bad, the scheduler 108 terminates the local iteration when the number of trials of the local iteration reaches the first specified number of times. That is, the scheduler 108 adaptively controls the execution of the local iteration and the global iteration depending on the convergence status of the iterative decoding process. Hence, the scheduler 108 can prevent possible early termination and late termination described above.

As described above, the receiver according to the sixth embodiment performs evaluation by focusing on the statistical value of the fourth reliability information (for example, the log-likelihood ratio in the LDPC decoder) and the change in the statistical value (the increase in the statistical value). The receiver uses a good convergence status as at least a part of the condition for continuing the local iteration and uses a bad convergence status as at least a part of the condition for terminating the local iteration while resuming the global iteration. Thus, the receiver adaptively controls the execution of the local iteration and the global iteration depending on the convergence status of the iterative decoding process. Hence, the receiver can prevent possible early termination and late termination described above.

The processing in the above-described embodiments can be implemented using a general-purpose computer as basic hardware. A program implementing the processing in each of the above-described embodiments may be stored in a computer readable storage medium for provision. The program is stored in the storage medium as a file in an installable or executable format. The storage medium is a magnetic disk, an optical disc (CD-ROM, CD-R, DVD, or the like), a magnetooptic disc (MO or the like), a semiconductor memory, or the like. That is, the storage medium may be in any format provided that a program can be stored in the storage medium and that a computer can read the program from the storage medium. Furthermore, the program implementing the processing in each of the above-described embodiments may be stored on a computer (server) connected to a network such as the Internet so as to be downloaded into a computer (client) via the network.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A receiver comprising:
a symbol de-mapper configured to carry out a symbol de-mapping process of calculating first reliability information indicative of a result of estimation of each bit forming received symbols, the first reliability information being calculated based on the received symbols and second reliability information corresponding to second extrinsic information;
a first extrinsic information calculation unit configured to calculate a difference between the first reliability information and the second reliability information to obtain first extrinsic information;
an LDPC decoder configured to carry out an iterative decoding process of iteratively calculating fourth reliability information indicative of a result of estimation of each bit forming the received symbols based on third reliability information corresponding to the first extrinsic information;
a second extrinsic information calculation unit configured to calculate a difference between the third reliability information and the fourth reliability information to obtain the second extrinsic information when local iteration comprising the iterative decoding process terminates;
a generation unit configured to generate a convergence indicator for evaluating a convergence status of the iterative decoding process based on the fourth reliability information; and
a scheduler configured to control execution of the local iteration and to control execution of global iteration comprising alternation between the symbol de-mapping process and the iterative decoding process, based on the convergence indicator.

2. The receiver according to claim 1, wherein, based on the convergence indicator, the scheduler determines to continue or terminate the local iteration and further to resume or terminate the global iteration when the scheduler determines to terminate the local iteration.

3. The receiver according to claim 1, wherein the convergence indicator includes a total number of bits failing to meet a parity constraint condition.

4. The receiver according to claim 1, wherein the convergence indicator includes a change in a total number of bits failing to meet a parity constraint condition.

5. The receiver according to claim 1, wherein the convergence indicator includes a total number of bits failing to meet a parity constraint condition and a change in the total number of bits failing to meet the parity constraint condition.

6. The receiver according to claim 1, wherein the convergence indicator includes a statistical value of the fourth reliability information.

7. The receiver according to claim 1, wherein the convergence indicator includes a change in a statistical value of the fourth reliability information.

8. The receiver according to claim 1, wherein the convergence indicator includes a statistical value of the fourth reliability information and a change in the statistical value of the fourth reliability information.

9. The receiver according to claim 1, wherein the scheduler determines to terminate both the local iteration and the global iteration when a total number of bits failing to meet a parity constraint condition is zero.

10. The receiver according to claim 1, further comprising:
a de-interleaver configured to carry out a de-interleave process on the first extrinsic information to obtain the third reliability information; and
an interleaver configured to carry out an interleave process corresponding to the de-interleave process on the second extrinsic information to obtain the second reliability information.

11. A receiving method comprising:
carrying out a symbol de-mapping process of calculating first reliability information indicative of a result of estimation of each bit forming received symbols, the first reliability information being calculated based on the received symbols and second reliability information corresponding to second extrinsic information;
calculating a difference between the first reliability information and the second reliability information to obtain first extrinsic information;
carrying out an iterative decoding process of iteratively calculating fourth reliability information indicative of a result of estimation of each bit forming the received symbols based on third reliability information corresponding to the first extrinsic information;
calculating a difference between the third reliability information and the fourth reliability information to obtain the second extrinsic information when local iteration comprising the iterative decoding process terminates;
generating a convergence indicator for evaluating a convergence status of the iterative decoding process based on the fourth reliability information; and
controlling execution of the local iteration and controlling execution of global iteration comprising alternation between the symbol de-mapping process and the iterative decoding process, based on the convergence indicator.
